(19) United States
(12) Patent Application Publication
(10) Pub. No.: US 2025/0293019 A1
(43) Pub. Date: Sep. 18, 2025

(54) ETCH STOP LAYER IN ALL-IN-ONE HARC ETCH

(71) Applicant: Tokyo Electron Limited, Tokyo (JP)

(72) Inventors: Alec Dorfner, Albany, NY (US); Minjoon Park, Albany, NY (US)

(21) Appl. No.: 18/603,023

(22) Filed: Mar. 12, 2024

(51) Int. Cl. H01L 21/02; H01L 21/311; H01L 21/768; H01L 23/532; H10B 41/10; H10B 41/27; H10B 41/35; H10B 43/10; H10B 43/27; H10B 43/35

(52) U.S. Cl. CPC H01L 21/0228; H01L 21/02164; H01L 21/0217; H01L 21/31144; H01L 21/76832; H01L 21/76877; H01L 23/53295; H10B 41/10; H10B 41/27; H10B 41/35; H10B 43/10; H10B 43/27; H10B 43/35

(57) ABSTRACT

A method of forming a device includes receiving, in a processing chamber, a substrate having a layer stack comprising an etch stop layer, a stack of alternating oxide and nitride layers, and a patterned hard mask layer, the patterned hard mask layer comprising a pattern for forming a first features and a second features in the layer stack, the first features having a different geometric characteristic than the second features. And the method further includes performing, in the processing chamber, a cyclic etch process to expose an underlayer, each cycle of the cyclic etch process including a first etch step to etch through the alternating oxide and nitride layers, and a second etch step to etch through the etch stop layer.

### TECHNICAL FIELD

The present invention relates generally to the field of semiconductor manufacturing, and, more specifically, to a semiconductor fabrication method with an all-in-one etch process using a plurality of etch stop layers.

### BACKGROUND

Conventional NAND flash memory devices have historically been fabricated using planar (2D) structures. These planar NAND devices are limited in their ability to scale down in size, leading to difficulties in increasing memory densities while maintaining acceptable performance and reliability. The limitations of 2D NAND flash memory are primarily attributed to issues such as cell-to-cell interference, data retention, and programming/erasing endurance.

To overcome these limitations, the semiconductor industry has transitioned to 3D NAND technology, which offers a fundamentally different architecture. In 3D NAND devices, memory cells (transistors) are stacked vertically in multiple layers, allowing for a significant increase in storage capacity without the need for aggressive scaling of planar structures. Vertical stacking of memory cells enables each layer to be accessed independently, reducing cell-to-cell interference and improving overall memory device performance.

While various techniques have been developed for 3D NAND fabrication, there remains room for innovation and improvement in the field. Current fabrication methods incorporate non-selective etch processes that incorporate multiple discrete etch steps to etch the various features (such as contacts and slits) of different critical dimensions (CDs) and different shapes of the 3D NAND devices. Conventional 3D NAND fabrication methods etch layer stacks comprising alternating silicon oxide and silicon nitride layers (ON).

### SUMMARY

A method of forming a device includes receiving, in a processing chamber, a substrate having a layer stack comprising an etch stop layer, a stack of alternating oxide and nitride layers, and a patterned hard mask layer, the patterned hard mask layer comprising a pattern for forming a first features and a second features in the layer stack, the first features having a different geometric characteristic than the second features. And the method further includes performing, in the processing chamber, a cyclic etch process to expose an underlayer, each cycle of the cyclic etch process including a first etch step to etch through the alternating oxide and nitride layers, and a second etch step to etch through the etch stop layer.

A method of forming a device includes receiving, in a processing chamber, a substrate having a layer stack and a patterned hard mask layer, the patterned hard mask layer comprising a pattern for forming a first features and a second features in the layer stack, the layer stack comprising alternating layers of a first pair and a second pair, the first pair comprising an etch stop layer and a first layer, and the second pair comprising a second layer and a third layer made of a same material as the first layer. And the method further includes performing, in the processing chamber, a cyclic etch process, each cycle of the cyclic etch process including using the patterned hard mask layer as an etch mask, performing a first etch process to expose the etch stop layer of the first pair, the first etch process selectively etching the first layer, the second layer, and the third layer to form a portion of the first features and a portion of the second features, the first features being etched at a different etch rate than the second features. The cyclic etch process further includes performing a second etch process to etch through the etch stop layer of the first pair of the layer stack, the second etch process selectively etching the etch stop layer. And where the cyclic etch process is performed until an underlayer below the layer stack is exposed.

And a method of forming a 3D NAND device includes receiving, in a processing chamber, a substrate comprising an underlayer, a first layer pair of an etch stop layer and a silicon oxide layer, and a plurality of second layer pairs, each second layer pair of the plurality of second layer pairs comprising a silicon nitride layer and a silicon oxide layer, the first layer pair and the plurality of second layer pairs being stacked to form a layer stack. The method further includes determining a total number of first layer pairs in the layer stack, where the total number of first layer pairs is at least 4. The method further includes determining a number of etch cycles for a cyclic etching process based on the total number of first layer pairs. The method further includes etching, in the processing chamber, a plurality of gate patterns and channel holes through the layer stack using the cyclic etching process, the cyclic etching process being repeated for the number of etch cycles, each cycle of the cyclic etch process including a first etching process to selectively etch the silicon oxide layers and the silicon nitride layers and a second etching process to selectively etch the etch stop layers. And the method further includes performing, in the processing chamber, a pull process to etch the silicon nitride layers and the etch stop layers of the layer stack.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic diagram of a semiconductor device which may be fabricated using a fabrication method of this disclosure according to an embodiment;

FIG. 2 is a flowchart illustrating a method of fabricating a semiconductor device according to an embodiment;

FIGS. 3A-3N, 3O1-3O2, and 3P-3Q are cross-sectional view schematic diagrams each illustrating a step of the method of fabricating a semiconductor device according to an embodiment;

FIG. 4 is a plot illustrating an etching intensity as a function of time for an etch step of the method of fabricating a semiconductor device according to an embodiment;

FIGS. 5A-5C are cross-sectional view schematic diagrams illustrating different etch stop layers used in the method of fabricating a semiconductor device of this disclosure according to various embodiments; and

FIG. 6 is a system diagram of a plasma etching tool implementing the etch step of the method of fabricating a semiconductor device of this disclosure according to an embodiment.

### DETAILED DESCRIPTION OF ILLUSTRATIVE EMBODIMENTS

In the process of fabricating a semiconductor device, etching is an essential step for creating a multitude of microscopic features and structures like vias, trenches, contact holes, gates, and fin structures. The etching process involves removing material from a layer stack disposed on a semiconductor wafer to produce these features, usually achieved via dry or wet etching methods. However, achieving the desired level of precision during etching is a challenging task, especially in modern semiconductor devices where the dimensions of the features are continually miniaturizing following Moore's law. Further, when etching multiple features simultaneously, the different features may have significantly different etch rates depending on their critical dimension (CD) or pattern (i.e., channel hole and slit). As a result of the different etch rates, etching can lead to over-etching or under-etching, impacting the dimensional accuracy of features and potentially damaging the underlying layers or conductive structures of the semiconductor device.

This disclosure describes an innovative method for fabricating a semiconductor device using multiple etch stop layers which may be used in the semiconductor device. This technique comprises employing a series of etch stop layers in strategic positions during fabrication to enhance the precision of etching and safeguard the underlying structures or layers. The use of multiple etch stop layers enables the etching processes to etch various features of differing etch rates simultaneously, which combines conventional etch steps and reduces the amount of fabrication steps to manufacture a semiconductor device. The method described in this disclosure addresses and mitigates some challenges of conventional etching practices, resulting in a more accurate, reliable, and efficient method for fabricating semiconductor devices.

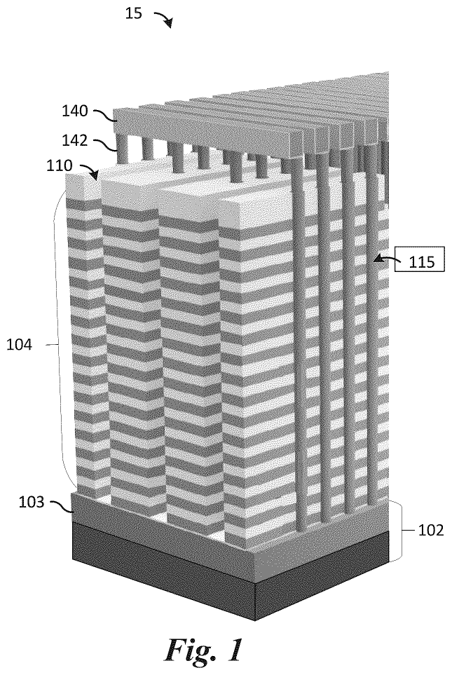

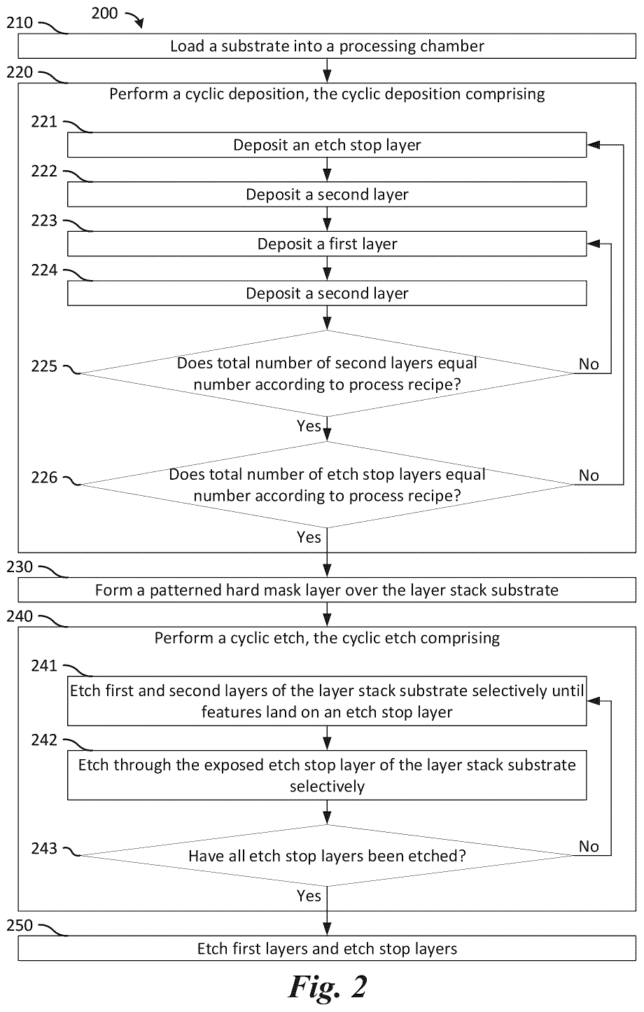

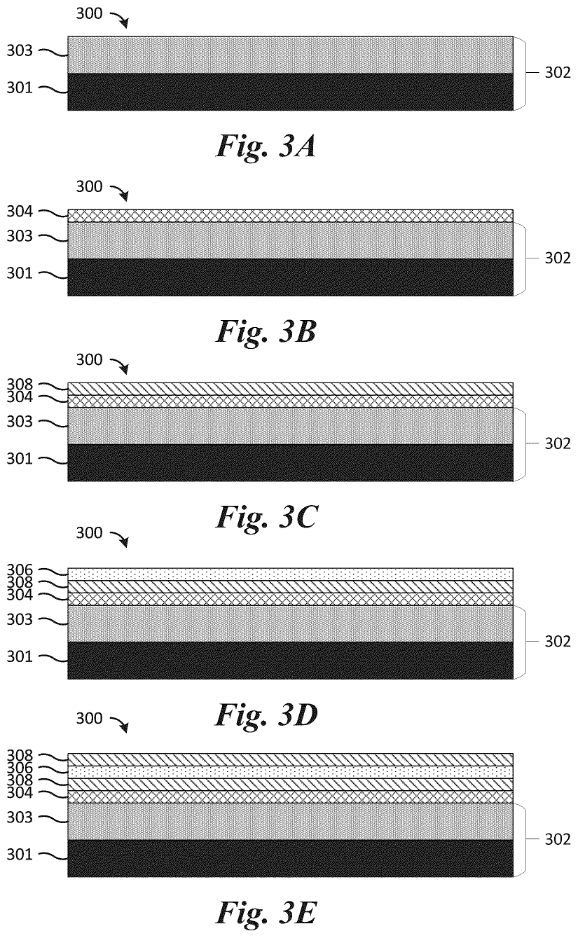

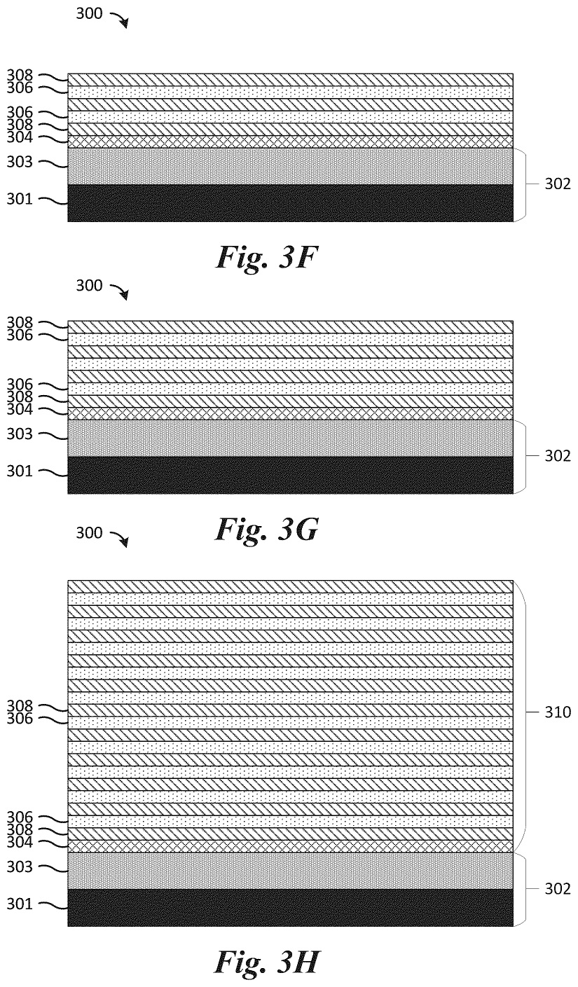

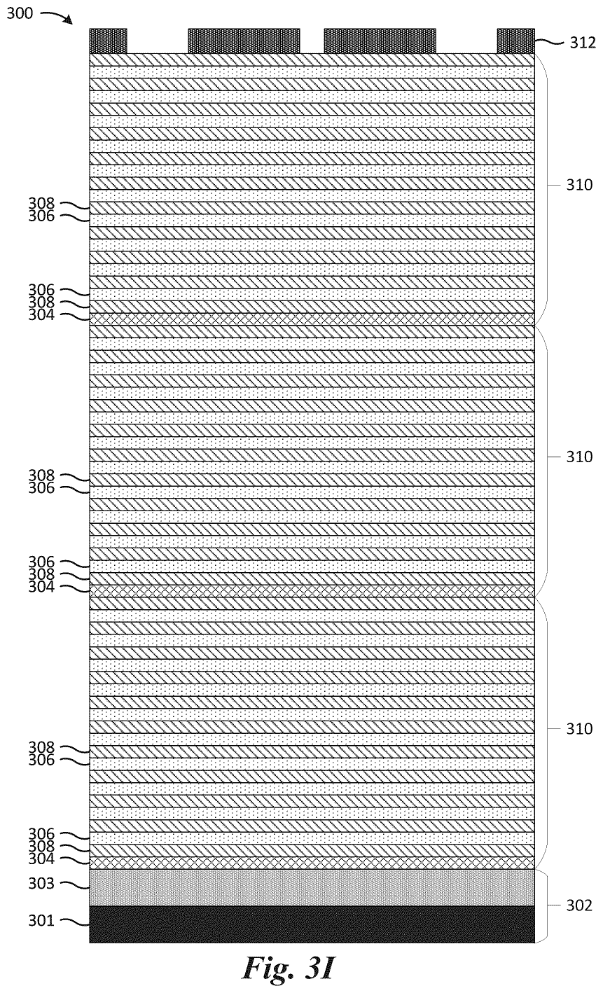

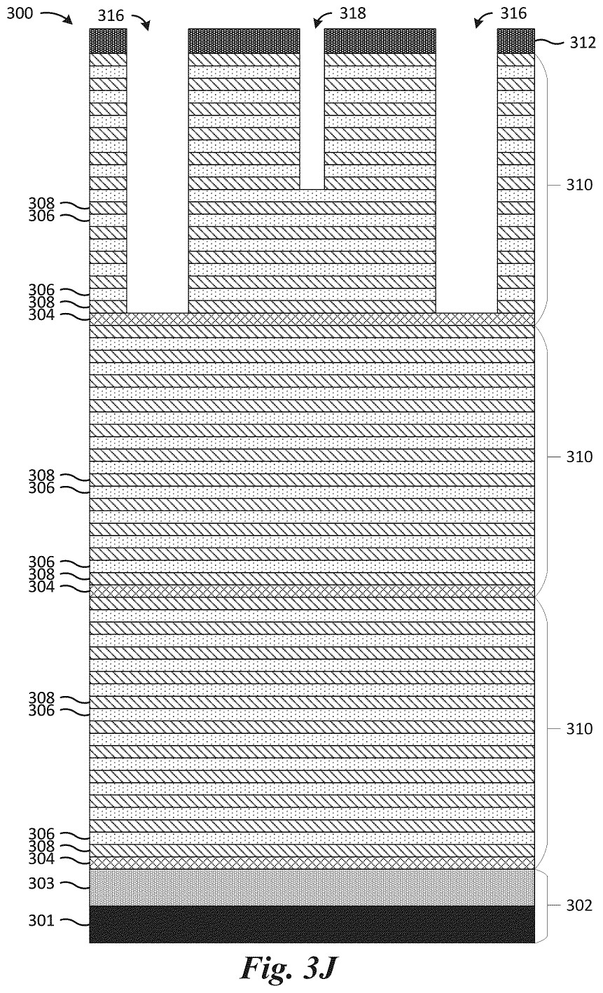

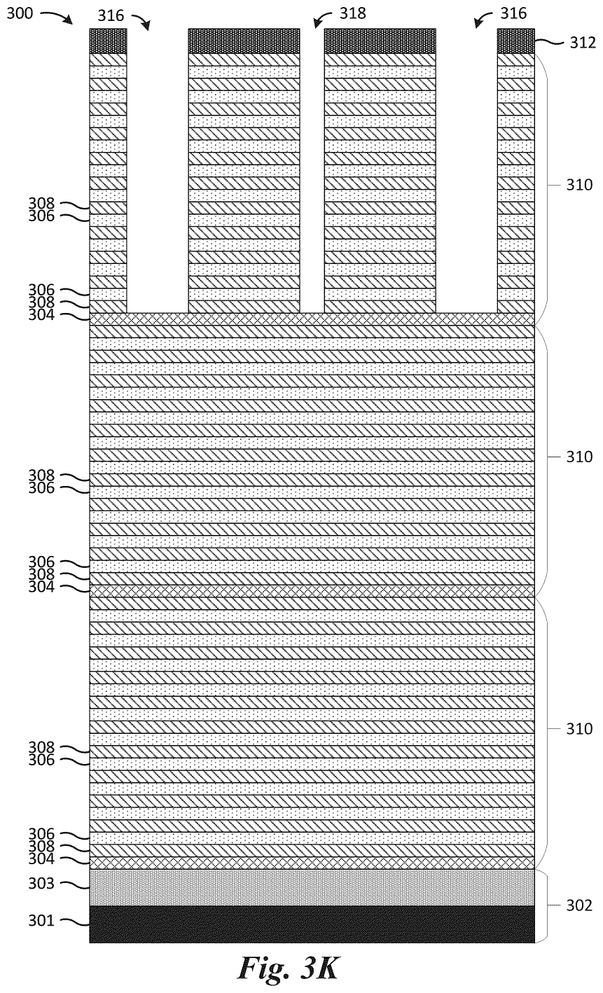

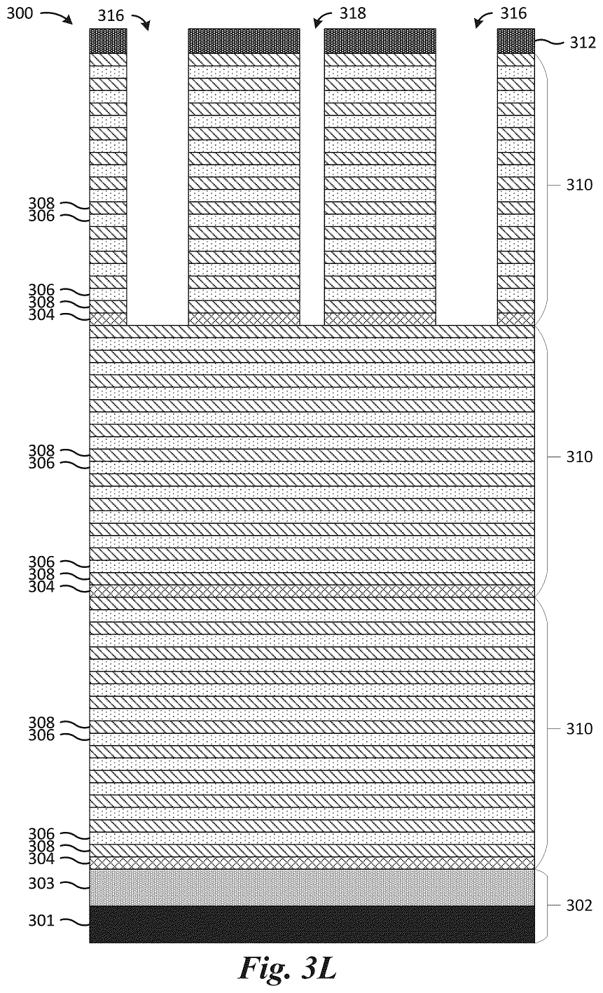

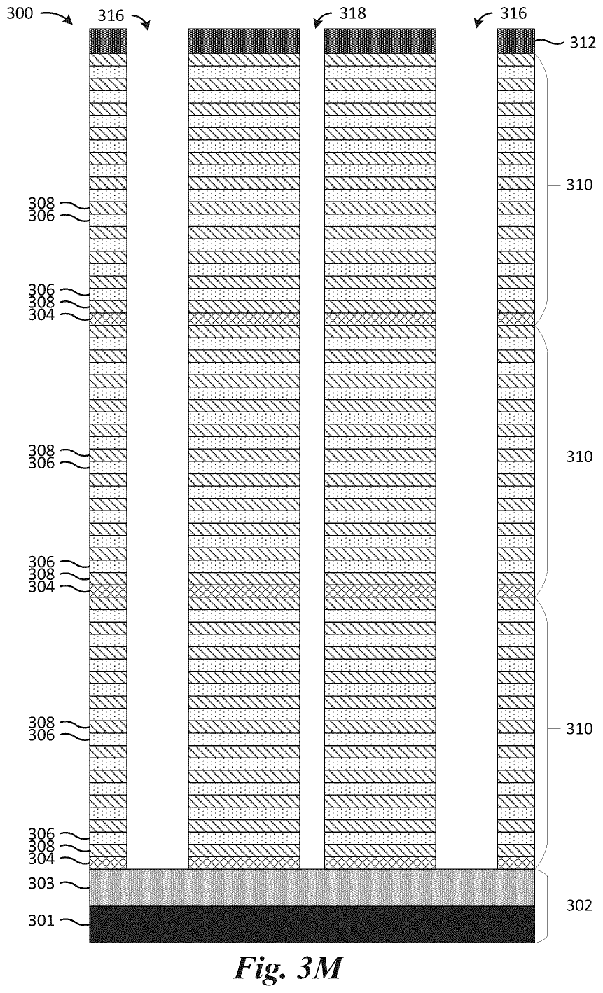

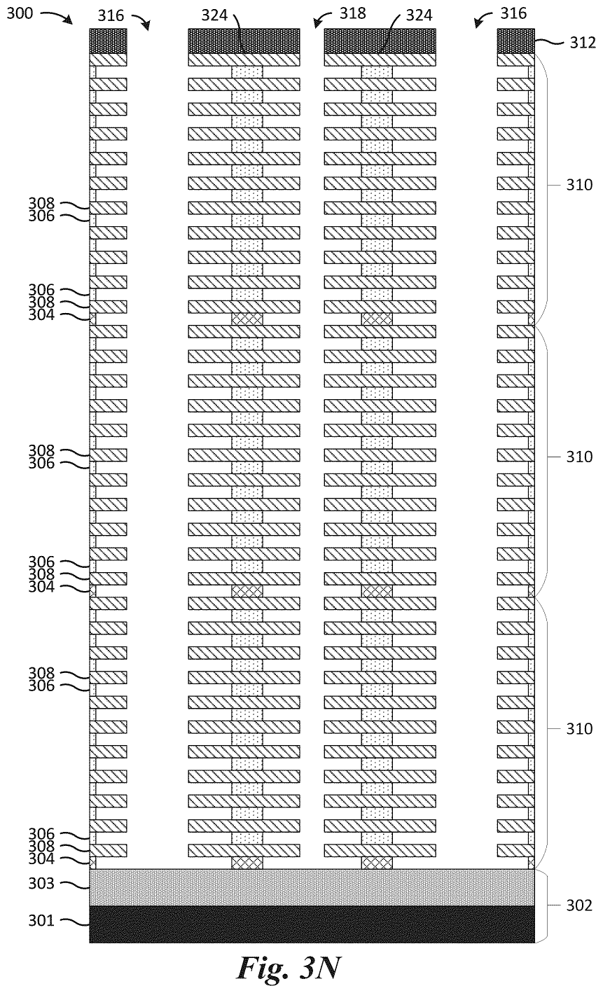

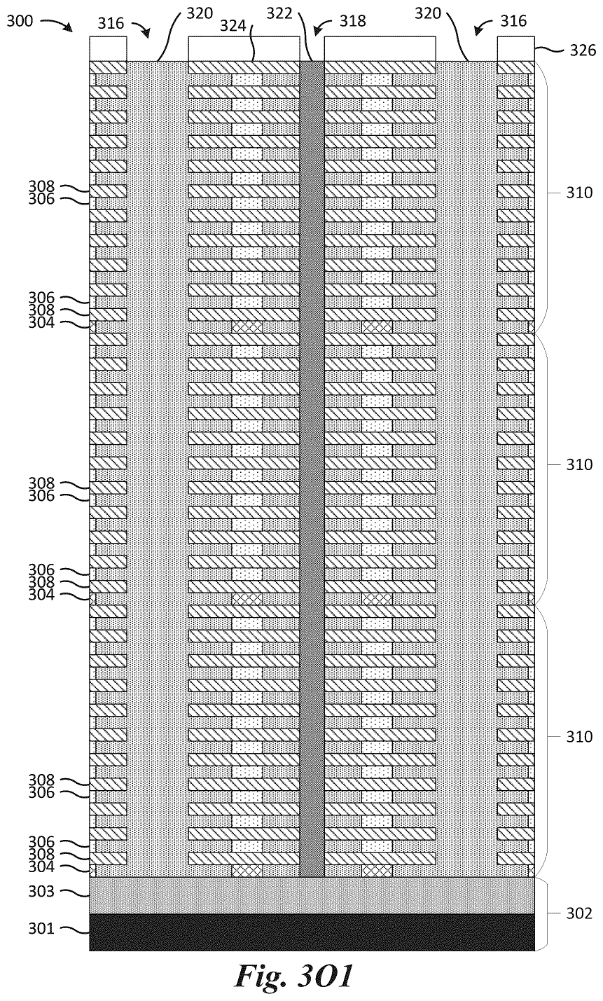

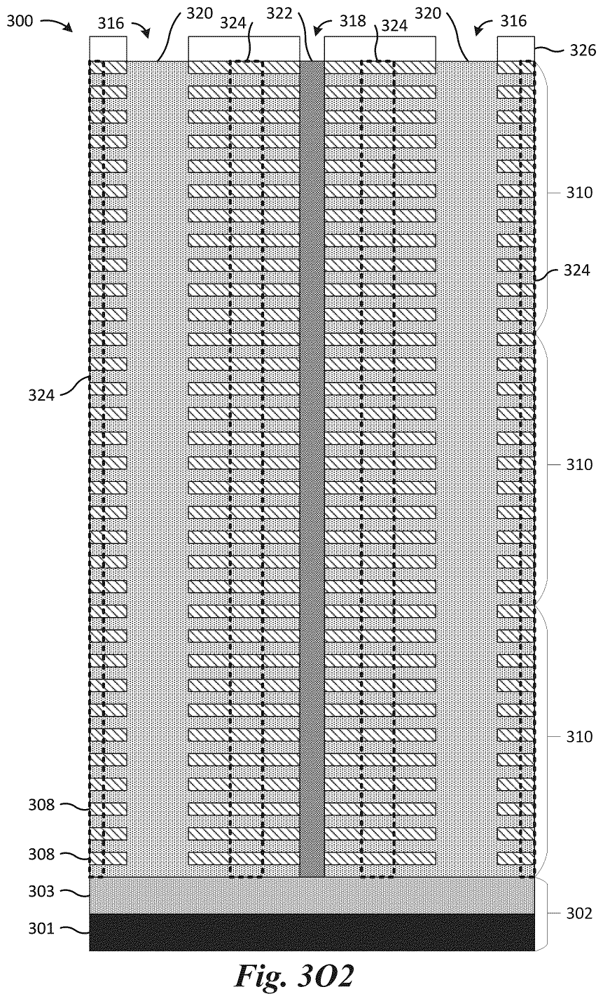

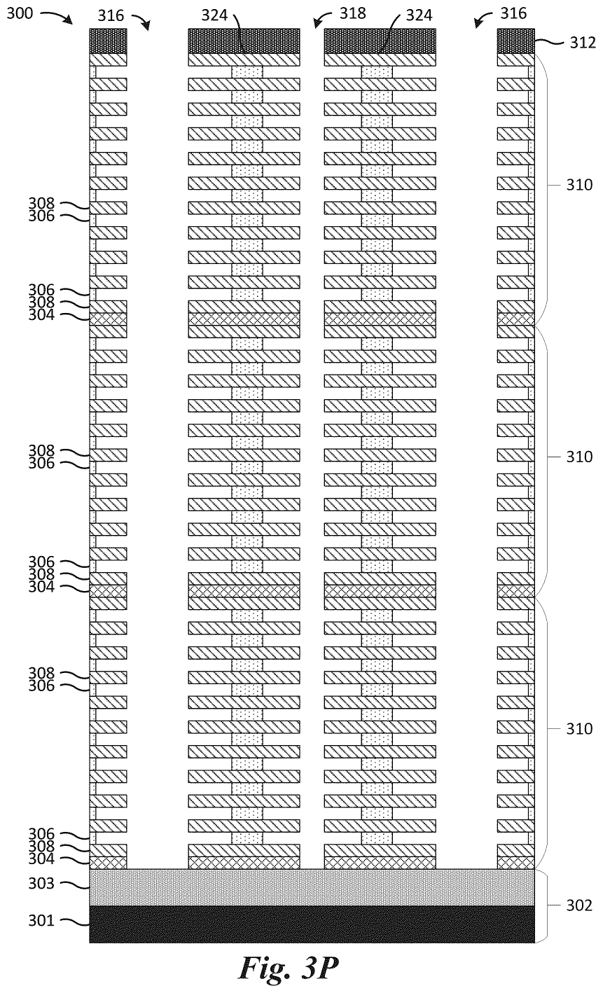

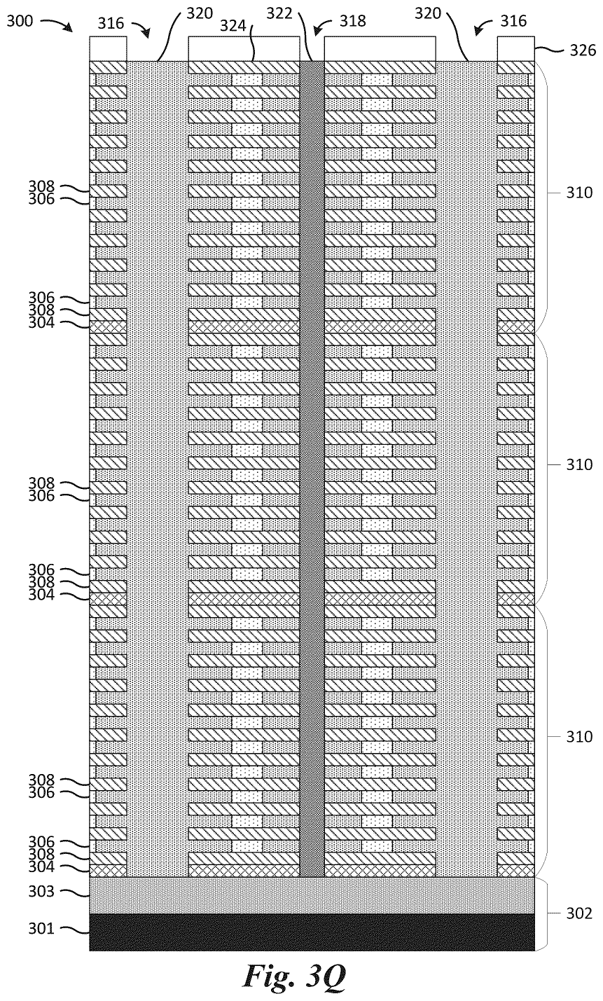

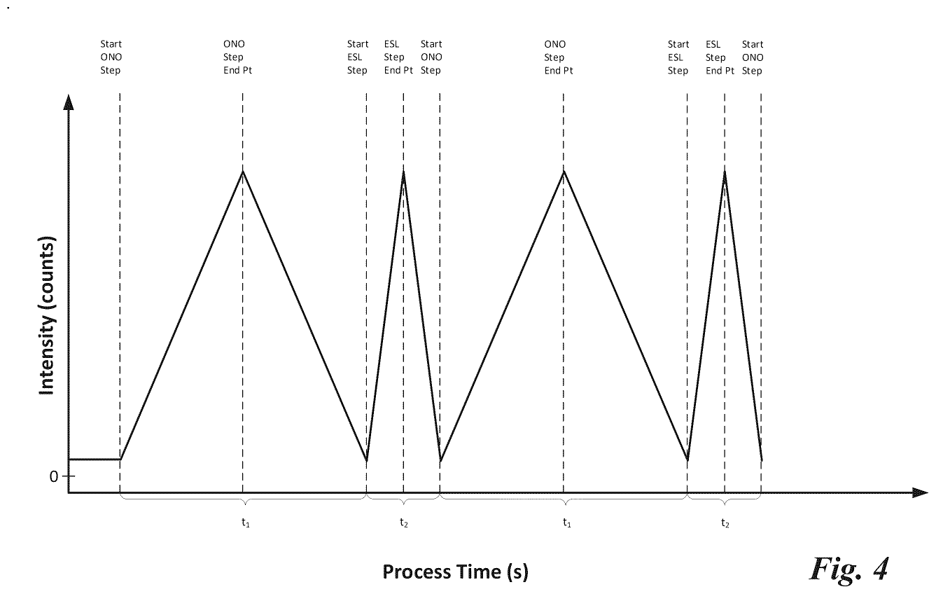

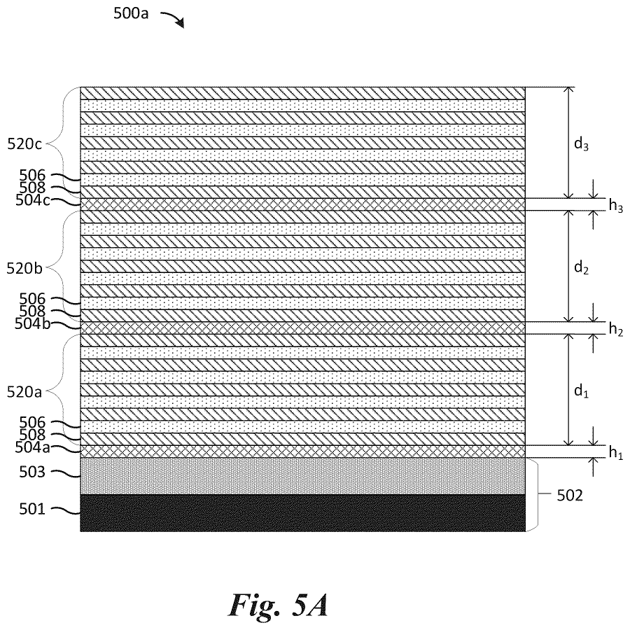

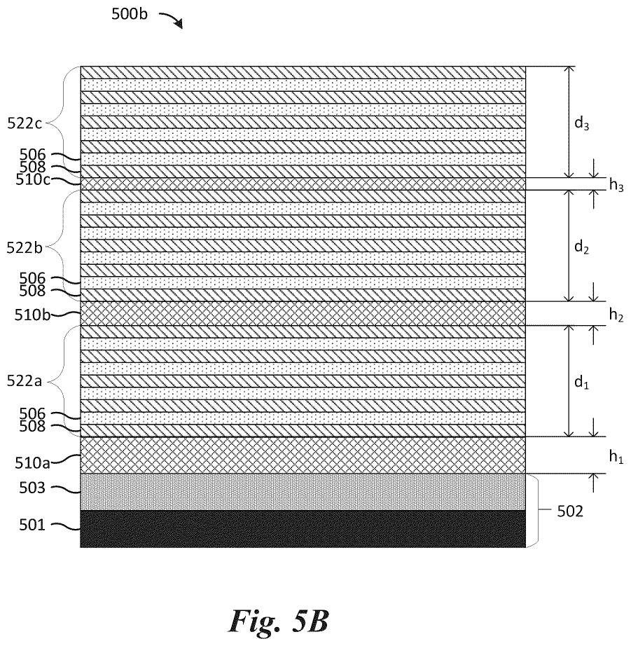

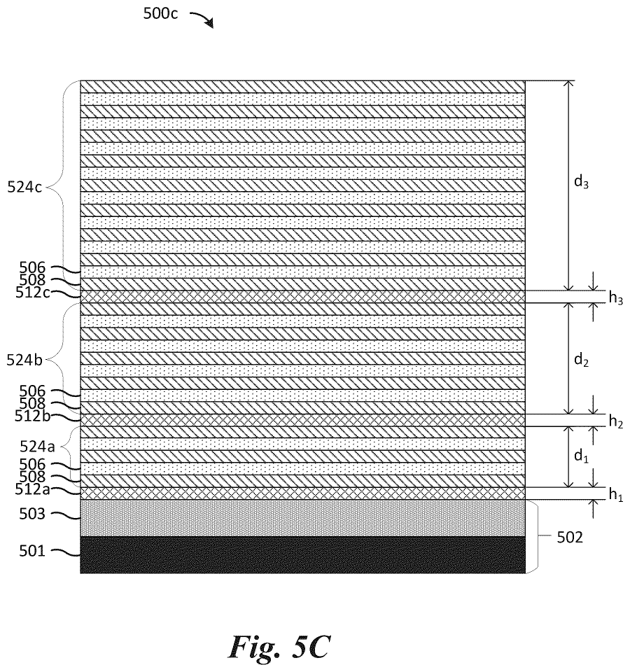

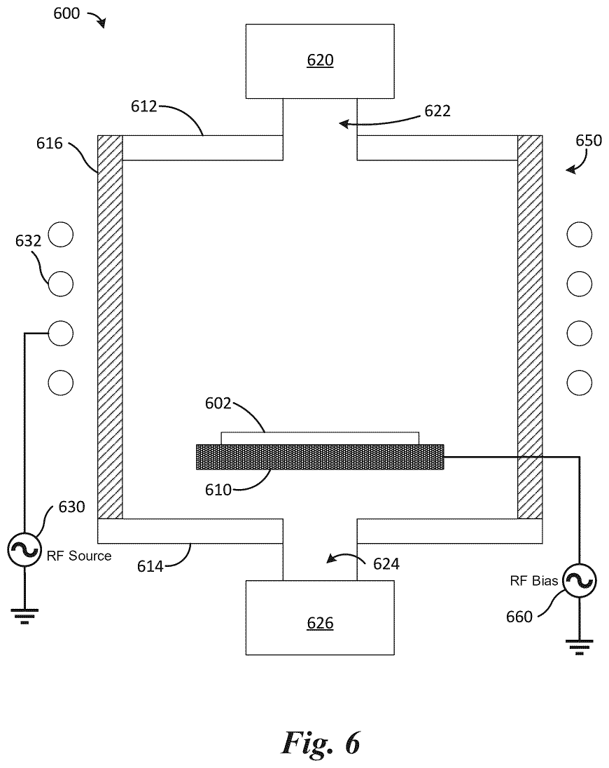

Embodiments provided below describe various methods for fabricating a semiconductor device, and in particular, methods using multiple etch stop layers to enable simultaneous etching of features of different etch rates to improve fabrication efficiency and the fabrication rate. The following description describes the embodiments. An example semiconductor device which may be fabricated using the method of this disclosure is illustrated in FIG. 1. An embodiment method of fabricating a semiconductor device using multiple etch stop layers is described using the flowchart illustrated in FIG. 2. The steps of the embodiment method of FIG. 2 are illustrated in the cross-sectional view schematic diagrams of FIGS. 3A-3Q. A plot of the etching intensity as a function of time for the cyclic etch process used in the fabrication method of this disclosure is illustrated in FIG. 4. Various etch stop layer embodiments are illustrated in the cross-sectional view schematic diagrams of FIGS. 5A-5C. And a plasma processing tool that may be used in the etching process of the fabrication method of this disclosure is illustrated in FIG. 6.

FIG. 1 illustrates a projection view of a semiconductor device with high aspect ratio contact (HARC) features that may be fabricated using an embodiment method with a cyclic etching process of this disclosure. This figure could be a 3D NAND memory device but, in different embodiments, other types of device structures with HARC features may be formed. FIG. 1 illustrates a semiconductor structure 15 after the method of fabricating a semiconductor device of this disclosure and also after some subsequent fill process for illustration.

The semiconductor structure 15 comprises a substrate 102, such as a semiconductor substrate and further comprises an underlayer 103. In various embodiments, the underlayer 103 may comprise a semiconducting material, a conducting material, or an etch stop layer. In other embodiments, the underlayer 103 may comprise integrated circuits fabricated thereon, such as driver circuits for a memory device. The semiconductor structure 15 comprises a layer stack 104 in which multiple layers of transistors are formed. The semiconductor structure 15 further comprises features of differing CDs having high aspect ratios (HARs), e.g., having aspect ratios greater than 1:10, e.g., 1:50. Examples include a trench or a split 110 filled with a gate material (illustrated as not being filled for clarity) and a channel hole 115 filled with a channel stack. The semiconductor structure 15, in an embodiment, may further comprise a metal filled bit line 140 coupled with a metal filled bit line contact (BLC) 142 coupled to the channel stack in the channel hole 115.

As a result of the various features of the example semiconductor structure 15 of FIG. 1, the fabrication process for FIG. 1 may benefit from the fabrication method using multiple etch stop layers with a cyclic etch process of this disclosure. Not only would the inclusion of multiple etch stop layers and the selectivity of the cyclic etching process of the fabrication method reduce over-etch of underlayers 103 of the semiconductor structure 15, but the fabrication process is simpler and does not depend on overall etch time.

FIG. 2 is a flowchart illustrating a method 200 for fabricating a semiconductor device using multiple etch stop layers. For example, the method 200 may be used to fabricate the semiconductor structure 15 illustrated in FIG. 1. The method 200 may start in box 210. In box 210, the method 200 loads a substrate into a processing chamber. In various embodiments, the processing chamber may be some form of capacitively coupled plasma (CCP) chamber. In other embodiments, the processing chamber may be any form of processing chamber appropriate for implementing the method 200, such as the processing chambers of deposition tools or etching tools.

After loading the substrate into the processing chamber, the method 200 proceeds to box 220. In box 220, a cyclic deposition process is used to deposit the various layers to fabricate the semiconductor device. For example, the various layers of the semiconductor device may be deposited using various deposition methods known in the art, such as sputtering, chemical vapor deposition (CVD), plasma enhanced chemical vapor deposition (PECVD), atomic layer deposition (ALD), molecular beam epitaxy (MBE), etcetera.

The cyclic deposition process may begin in box 221, where the method 200 deposits an etch stop layer. After depositing the etch stop layer, the cyclic deposition process of the method 200 proceeds to box 222. In box 222, a second layer is deposited over the etch stop layer to form a first pair. The first pair comprises the etch stop layer and the second layer disposed over the etch stop layer.

After depositing the second layer, the cyclic deposition process of the method 200 proceeds to box 223. In box 223, a first layer is deposited over the second layer. The cyclic deposition process of the method 200 may then proceed to box 224. In box 224, a layer of the same material as the second layer is deposited over the first layer to form a new second layer and complete a second pair. The second pair comprises the first layer and the second layer disposed over the etch stop layer. In other embodiments, the material of the layer deposited in box 224 may be different than the material of the second layer in box 222. In those embodiments, the layer deposited in box 224 may be a third layer, and the second pair would comprise the first layer and the third layer.

After depositing the second layer over the first layer in box 224, the cyclic deposition process determines whether the total number of second layers deposited is the same as the amount according to a specified number of second layers in a process recipe in box 225. In various embodiments, the process recipe comprises multiple specifications for the fabrication of the semiconductor device, such as the specified number of second layers and a specified number of etch stop layers. The determination made in box 225 has two possible results. The total number of second layers is either equal to the specified number of second layers in the process recipe (Yes), or the total number of second layers is not equal to the specified number of second layers in the process recipe (No).

If the total number of second layers is not equal to the specified number of second layers in the process recipe (No), the cyclic deposition process of the method 200 proceeds back to box 223. Once the method 200 is back at box 223, the method 200 deposits another first layer over the topmost second layer in box 223 and then deposits another second layer over the first layer in box 224. After depositing the second layer in box 224, the method 200 proceeds to box 225 and determines whether the total number of second layers is equal to the specified number of second layers in the process recipe again.

The cyclic deposition process of the method 200 continuously makes the determination in box 225 after each deposition of the second pair until the total number of second layers is equal to the specified number of second layers according to the process recipe. A layer stack is formed after the specified number of second layers have been deposited. The layer stack comprises one first pair, and a plurality of second pairs stacked over the first pair. After the method 200 in box 225 determines the total number of second layers is equal to the specified number of second layers according to the process recipe (the Yes condition), the method 200 proceeds along the Yes path to box 226.

A new determination is made in box 226 of the method 200. The new determination of box 226 determines whether the total number of etch stop layers is equal to the specified number of etch stop layers according to the process recipe. There are, again, two possible results of the new determination in box 226. Either the total number of etch stop layers is not equal to the specified number of etch stop layers according to the process recipe (No), or the total number of etch stop layers is equal to the specified number of etch stop layers according to the process recipe (Yes).

If the method 200 in box 226 determines the total number of etch stop layers is not equal to the specified number of etch stop layers according to the process recipe (No), the method 200 proceeds along the No path to box 221. And in box 221, a new etch stop layer is deposited. After, the cyclic deposition process continues through boxes 221-225 until a new layer stack has been deposited, and the new determination in box 226 is made again.

If the new determination in box 226 determines the total number of etch stop layers is not equal to the specified number of etch stop layers according to the process recipe (No), the cyclic deposition process of the method 200 will again proceed along the No path to box 221, and another new layer stack will be deposited. The method 200 will again make the determination in box 225 until the method 200 determines the Yes condition of box 225 and proceeds to box 226. And the method 200 in box 226 determines whether the total number of etch stop layers is equal to the specified number of etch stop layers according to the process recipe.

Once the method 200 in box 226 determines the total number of etch stop layers is equal to the specified number of etch stop layers in the process recipe (the Yes condition), the method 200 has completed the cyclic deposition process of box 220 and a plurality of layer stacks has been formed over the substrate forming a layer stack substrate.

The method 200 proceeds along the Yes path to box 230. In box 230, the method 200 forms a patterned hard mask layer over the layer stack substrate. The deposition and patterning of the patterned hard mask layer may be accomplished using a suitable method known in the art. The patterned hard mask layer may be patterned with a feature pattern, the feature pattern comprising more than one kind of feature to be etched into the layer stack substrate, such as a first features and a second features. The first features and second features may be combinations of channel holes, vias, slits, trenches, or other features used in semiconductor devices, such as contact vias and slits.

After forming the patterned hard mask layer in box 230, the method 200 proceeds to box 240. In box 240, the method 200 performs a cyclic etch process to etch the feature pattern of the patterned hard mask layer. The cyclic etch process may begin in box 241 where the method 200 may use a first etch recipe (or a first etch process) to selectively etch the first layers and the second layers of the topmost layer stack until the first features and the second features land on the topmost etch stop layer.

The selectivity of the first etch recipe in box 241 etches the materials of the first layer and the second layer with a faster etch rate than the material of the etch stop layer. As a result, features of different etch rates may be simultaneously etched without punching through the etch stop layer and damaging underlying layers. Features with a faster etch rate will land on the topmost etch stop layer before features of slower etch rates, but the selectivity of the etch process in box 241 prevents the features of a faster etch rate from punching through the topmost etch stop layer and gives the fabrication process enough time to fully etch the features of the slower etch rate.

After the features land on the topmost etch stop layer, the cyclic etch process of the method 200 proceeds to box 242. In box 242, the method 200 switches to a second etch recipe to punch through the topmost etch stop layer. The selectivity of the second etch recipe (or second etch process) in box 242 etches the material of the etch stop layers at a faster etch rate than the material of the first layer and the material of the second layer. As a result, the various features of different etch rates may be etched through the topmost etch stop layer without excessive over-etch of the underlying second layer.

Once the method 200 has punched through the topmost etch stop layer in box 242, the method 200 proceeds to determine whether all of the etch stop layers of the semiconductor device have been punched through in box 243. There are two possible results of the determination made in box 243. Either a total number of etch stop layers punched through is equal to the specified number of etch stop layers according to the process recipe (Yes), or the total number of etch stop layers punched through is not equal to the specified number of etch stop layers according to the process recipe (No).

If the total number of etch stop layers punched through is not equal to the specified number of etch stop layers according to the process recipe (the No condition), the method 200 proceeds along the No path back to box 241. After the method 200 reaches box 241, the steps described above for boxes 241-242 are performed again, and the determination in box 243 is made until the Yes condition is met. For example, in an embodiment where the semiconductor device has three etch stop layers, the cyclic etch process of the method 200 will perform the steps described in boxes 241-243 three times until the total number of etch stop layers punched through is equal to the specified number of etch stop layers of the pattern recipe (the Yes condition of box 243).

If the determination in box 243 of the method 200 finds the total number of etch stop layers punched through is equal to the specified number of etch stop layers according to the process recipe (the Yes condition), the cyclic etch process of box 240 is finished and the method 200 proceeds to box 250. In box 250 the method 200 etches the first layers and etch stop layers in a material pull. The etching of the first layers and etch stop layers may be done by any suitable process known in the art. For example, if the material of the first layer is silicon nitride, a conventional nitride pull etch process that also pulls the material of the etch stop layer may be performed such as a wet etch process using hot phosphoric acid.

Conventional methods use etch stop layers as sacrificial layers, and do not incorporate the etch stop layers as a part of the semiconductor device. Typically, the conventional method uses a single etch stop layer at the bottom of a large layer stack, and forms the device over the sacrificial etch stop layer. The etching process of box 250 of the method 200 is performed in a manner such that the etch stop layer is kept as a component of the semiconductor device, which differs from conventional methods known in the art. In other words, the method 200 uses multiple etch stop layers that are kept and incorporated as components of the semiconductor device. In an embodiment, rather than the etch stop layers being incorporated into the semiconductor device, the etch stop layers may remain and will just serve as a small portion of wasted height in the semiconductor device.

In various embodiments, subsequent fill and further fabrication steps may be performed to finish fabricating the semiconductor device. For example, a conductive material may be used to fill the pulled first layers and pulled etch stop layers etched in box 250 to form the semiconductor device. In an embodiment, further fill and fabrication steps may be performed such that the semiconductor structure 15 illustrated in FIG. 1 is formed. An embodiment fabrication process of the method 200 is illustrated in the cross-sectional view schematic diagrams of FIGS. 3A-3Q.

FIGS. 3A-3Q are cross-sectional view schematic diagrams of a semiconductor device 300 being fabricated using the method 200 according to an embodiment of this disclosure. Each of FIGS. 3A-3Q illustrate a cross-sectional view schematic diagram of the semiconductor device 300 which comprises an underlayer 303 disposed above a wafer 301 to form a substrate 302. The cross-sectional schematic diagrams in FIGS. 3A-3Q illustrate a portion of the semiconductor device 300, but in various embodiments the semiconductor device 300 extends further left and further right.

The wafer 301 of FIG. 3A may be a silicon wafer, or any wafer appropriate for fabricating the semiconductor device 300. For example, the wafer may be any semiconducting substrate known in the art, such as monocrystalline silicon, IV-IV compounds such as silicon-germanium or silicon-germanium-carbon, III-V compounds, II-VI compounds, epitaxial layers over such substrates, electrically conductive layers (e.g., electrodes and/or interconnects) over such substrates, or any other semiconducting or non-semiconducting material, such as silicon oxide, glass, plastic, metal or ceramic substrate. The underlayer 303 may comprise integrated circuits fabricated on the wafer 301, such as driver circuits for a memory device. In other embodiments, the underlayer 303 may be a layer of a semiconducting material, of a conducting material, or of an insulating material.

FIG. 3B illustrates the semiconductor device 300 after depositing an etch stop layer 304 according to the method 200 in box 221. FIG. 3C illustrates the semiconductor device 300 after depositing a second layer 308 over the etch stop layer 304 in box 222. In various embodiments, the etch stop layer 304 may be any material not etched by conventional ONO etch recipes and capable of being etched along with layers of the semiconductor device in a pull process or similar wet etch of nitride layers (or oxide layers in other embodiments). For example, the etch stop layer 304 may be HfO₂, Al₂O₃, TiO₂, amorphous carbon layer (ACL), diamond-like carbon (DLC), ALC, SP³ Carbon, MgO, Ta₂O₃, AlSiO₃, HfSiO₃, AlN, or etcetera. In various embodiments, the material of the second layer 308 may be any suitable material for the fabrication of the semiconductor device including oxides, such as silicon oxide, or other suitable materials.

FIG. 3D illustrates the semiconductor device 300 after depositing a first layer 306 over the second layer 308 in box 223. The second layer 308 illustrated in FIG. 3E may be the second layer 308 deposited over the first layer 306 in box 224 of the method 200. In various embodiments, the first layer 306 may be any suitable material for the fabrication of the semiconductor device, such as silicon nitride, or a different material than the material of the second layers 308 and etch stop layer 304.

FIG. 3F illustrates the semiconductor device 300 after the check in box 225 of the method 200 determined the total number of second layers 308 did not equal the specified number of second layers in the process recipe. As a result, the method 200 proceeded on the No path of box 225 to box 223 and a new layer pair comprising a first layer 306 and a second layer 308 were deposited according to the steps described in boxes 223 and 224 of the method 200.

As further examples, FIGS. 3G-3H illustrate the semiconductor device 300 after repeating the steps in boxes 223, and 224, and the check in box 225 of the method 200 to deposit different amounts of layer pairs. FIG. 3G illustrates an embodiment where the cyclic deposition process of the method 200 deposited two additional layer pairs. FIG. 3H illustrates an embodiment where the cyclic deposition process of the method 200 deposited an additional nine layer pairs to form a layer stack 310. Though FIGS. 3G-3H illustrate embodiments with three layer pairs and ten layer pairs comprising first and second layers, respectively, other embodiments may have more or less layer pairs. For example, in various other embodiments, the layer stack 310 may comprise between about two to about 128 layer pairs. Further, in other embodiments, the layer stack 310 may comprise between about two to about 600 layer pairs.

FIG. 3I illustrates an embodiment where the cyclic deposition process of the method 200 deposited three layer stacks 310 in the fabrication of the semiconductor device 300. Each layer stack 310 comprises an etch stop layer 304 with alternating first layers 306 and second layers 308 deposited over the etch stop layer 304. In the embodiment illustrated in FIG. 3I, the process recipe comprised three etch stop layers 304 for the specified number of etch stop layers 304 and eleven second layers 308 for the specified number of second layers 308.

The semiconductor device 300 illustrated in FIG. 3I further comprises a patterned hard mask layer 312 to be used to etch the various features in the forming of the semiconductor device 300. The patterned hard mask 312 may have been deposited and patterned using conventional methods, such as by depositing a hard mask layer, depositing a photoresist layer over the hard mask layer, patterning the photoresist layer using a lithography method to form a patterned photoresist layer, and then using the patterned photoresist layer to pattern the hard mask layer and form the patterned hard mask layer 312. The patterned hard mask layer 312 may have been deposited and patterned according to box 230 of the method 200 in FIG. 2 in an embodiment.

FIG. 3J illustrates the semiconductor device 300 after etching the feature recipe patterned in the patterned hard mask layer 312 into the alternating first layers 306 and second layers 308 of the layer stack 310 selectively. In an embodiment, the etch process used to etch the feature recipe in the patterned hard mask layer 312 may be the first selective etch process of the cyclic etch process described in box 241 of FIG. 2. The semiconductor device 300 in FIG. 3J further comprises a first feature 316 and a second feature 318 being etched into the layer stack 310. As illustrated in FIG. 3J, the first feature 316 has been etched at a faster etch rate than the second feature, and thus the first features 316 have been etched to a deeper layer than the second feature 318. In an embodiment, the first features 316 may be contact vias, and the second feature 318 may be a slit, or trench. In various embodiments, the first features 316 are a conventional semiconductor feature with a different etch rate than the second feature 318.

The difference in the etch rates between the first feature 316 and the second feature 318 causes the first feature 316 to be etched more rapidly than the second feature 318. In FIG. 3J, the first features 316 have landed on the first etch stop layer 304, and the second feature 318 has not. As a result, the semiconductor device 300 is etched an extended amount of time until the second feature 318 lands on the topmost etch stop layer 304. Because the first etch recipe used to etch the first feature 316 and the second feature 318 is selective to the material of the first layers 306 and material of the second layers 308, the topmost etch stop layer 304 will not permit the first etch recipe to punch through the topmost etch stop layer 304 and cause over-etch on the underlying layers. As a result, the second feature 318 of a slower etch rate may be etched for an extended amount of time until landing on the topmost etch stop layer 304 without punching through and over-etching underlying layers.

FIG. 3K illustrates the semiconductor device 300 after the first features 316 and the second feature 318 have all landed on the topmost etch stop layer 304. For example, the semiconductor device 300 illustrated in FIG. 3K may represent the semiconductor device formed after performing the steps of the method 200 through box 241 in FIG. 2.

After the features have landed on the topmost etch stop layer 304, the cyclic etch process switches to a second etch recipe that is selective to the material of the etch stop layer 304 to punch through and expose the topmost second layer 308 of the underlying layer stack 310. FIG. 3L illustrates the semiconductor device 300 after the topmost etch stop layer 304 has been punched through using the second etch recipe selective to the material of the etch stop layer, such as the step described above for box 242 of the method 200. FIG. 3L illustrates the first features 316 and the second feature 318 after landing on the topmost second layer 308 of the underlying layer stack 310.

FIG. 3M illustrates the semiconductor device 300 after the first features 316 and the second feature 318 have landed on the underlayer 303 of the substrate 302. For example, FIG. 3M may illustrate the semiconductor device 300 after processing through the method 200 and meeting the Yes condition of box 243 in FIG. 2. In other words, all of the etch stop layers 304 of the semiconductor device 300 have been etched (or punched through). After exposing the underlayer 303, the material of the first layers 306 and the etch stop layers 304 may be etched simultaneously using a suitable method.

FIG. 3N illustrates the semiconductor device 300 after using a suitable etch process to etch the material of the first layers 306 and the material of the etch stop layers 304 to further fabricate the semiconductor device 300 according to the process recipe and form a support structure 324. The support structure 324 comprises the remaining etch stop layers 304 and first layers 306, which may be used to stabilize the semiconductor device 300 during further processing steps. For example, an isotropic etch process selective to the material of the first layers 306 and the material of the etch stop layers 304 may be used. In an embodiment where the first layers 306 are silicon nitride, the etch process may be a conventional nitride pull method that is also selective to the material of the etch stop layers 304. As illustrated in FIG. 3N, the etch stop layers 304 are incorporated into the structure of the semiconductor device 300, and will remain a part of the semiconductor device 300 after fabrication is finished. In an embodiment, FIG. 3N illustrates the semiconductor device 300 after box 250 of the method 200 in FIG. 2.

As described above, further fabrication steps, such as conductive material fills to form contact vias or wordlines or a gate or a channel stack or other further processing steps, may be used to finish fabricating the semiconductor device 300. For example, the contacts may be completed by depositing a conductive material, such as Cu, W, Al, their alloys or a silicide.

An embodiment of the semiconductor device 300 is illustrated in FIGS. 3O1-2, where FIG. 3O1 and FIG. 3O2 are separate cross-sectional slices of the semiconductor device 300.

In an example, a channel stack 322 comprising polysilicon may be formed within the second feature 318. A gate material 320 may be used to fill the first features 316. The gate material 320 may include a gate stack and may comprise a gate dielectric followed by a stack of conductive materials.

FIG. 3O1 illustrates the semiconductor device 300 in a cross-sectional view that shows the support structure 324. FIG. 3O1 may illustrate the semiconductor device 300 after a conductive material was used to fill the first features 316 with the gate material 320. The second feature 318 was filled with channel material to form the channel stack 322. Another cross-sectional view of the semiconductor device 300 is illustrated in FIG. 3O2. The dashed boxes represent the channel stack 324, which may be disposed further back in the semiconductor device 300 and is not visible in the illustrated cross-sectional view of FIG. 3O2.

A mask layer 326 may be included, in certain embodiments, to enable filling of certain features and not others. For example, the mask layer 326 may have been used to cover the second feature 318 and to leave uncovered the first features 316 for filling with the gate material 320, which may be a different material than the conductive material to form the channel stack 322 with channel material.

In the case of a 3D memory device, channel material of the channel stack 322 may include any material(s) suitable for use as a channel (or portion of a channel) of the 3D memory device. In certain embodiments, channel material may include multiple material layers that include silicon, oxide, SiN, oxide, and silicon (e.g., SONOS structures). In certain embodiments, channel material may include tungsten, alumina, nitride, oxide, and silicon (e.g., WANOS structures). In certain embodiments, channel material may include an oxide-nitride-oxide (ONO) memory stack and polysilicon material to form the polysilicon channel. In certain embodiments, the second feature 318 of FIG. 3N may be filled with any of SiO₂, SiN, SiO₂ and polysilicon. For example, depositing channel material may include depositing a layer of oxide (e.g., SiO₂), a layer of nitride (e.g., SiN), and another layer of oxide (e.g., SiO₂), with a remaining portion of the second feature 318 being filled with polysilicon. Channel material may be deposited using any suitable type of deposition process or combination of deposition processes. For example, channel material may be deposited using one or more of a CVD process (including, potentially, an ALD process), a PECVD process, a PVD process, a PEPVD process.

As illustrated in FIGS. 301-2, the first features 316 of FIG. 3N may be filled with the gate material 320. The gate material 320 may be a metal-containing material appropriate for the corresponding fabrication process, such as for forming a 3D semiconductor structure (e.g., a 3D NAND device). In certain embodiments, the gate material 320 may be a metal-containing material suitable for use as a gate in the 3D semiconductor structure being formed. Although primarily described as a metal-containing material, the gate material 320 may be any suitable conductive material, such as any material that is suitable for acting as a gate in a transistor (e.g., a gate in a transistor of a 3D NAND memory device).

In another embodiment, rather than recessing both the first layers 306 and the etch stop layers 304 (as illustrated in FIG. 3N), only the first layer 306 may be recessed through a suitable etch process. For example, the etch stop layers 304 may etch at lower rate than the first layers 306. FIG. 3P illustrates the semiconductor device 300 after using a suitable etch process to etch the material of the first layers 306 to further fabricate the semiconductor device 300 according to the process recipe and form a support structure 324. The support structure 324 comprises the remaining etch stop layers 304 (that have not been recessed) and first layers 306, which may be used to stabilize the semiconductor device 300 during further processing steps. For example, an isotropic etch process selective to the material of the first layers 306 may be used. Similar to FIG. 3O1, FIG. 3Q illustrates the semiconductor device 300 after filling the first features 316 with the gate material 320. Similarly labeled elements may be as previously described. In an embodiment, an example plot of the etching intensity as a function of time for the cyclic etch process in box 240 of the method 200 is illustrated in FIG. 4.

FIG. 4 is a plot of etching intensity as a function of time which illustrates the cyclic etching process of the fabrication method 200 of FIG. 2 in an embodiment. The etching intensity over time plot of FIG. 4 illustrates an embodiment where the cyclic etching process incorporates a constant timeframe for both selective etch steps of the cyclic etch process. In other embodiments, the timeframe for each selective etch step may vary to account for changes in the spacing between etch stop layers, or changes in the thicknesses of etch stop layers, or a combination of both, such as the etch stop layer embodiments illustrated in FIGS. 5A-5C.

The etching intensity as a function of time plot of FIG. 4 is illustrated for an embodiment where the cyclic etch process is intended to etch a layer stack substrate of alternating silicon oxide layers and silicon nitride layers as the first layers and second layers, respectively. In an embodiment where the alternating first layers and second layers are silicon oxide layers and silicon nitride layers, the layer stack may be called an oxide-nitride-oxide layer stack, or ONO layer stack. Consequently, the ONO Step corresponds to the first selective etch step of the etch cycle in box 241 of the method 200, and the etch stop layer (ESL) Step corresponds to the second selective etch step of the cyclic etch process in box 242 of the method 200.

FIG. 4 is a plot of the etching intensity over time for a version of the cyclic etching process with a constant first etch time (t₁) and second etch time (t₂) of the etch cycle. The etching intensity may be an optical emission spectroscopy signal as just one example technique to measure etch intensity. For example, in an embodiment where the etching tool comprises a plasma etcher, a gas analyzer may be used to monitor the composition of the outflow gas from a plasma etch chamber during the etching. As a result, the total time of the cyclic etching process depends on the total number of etch stop layers and the total number of second layers according to the process recipe.

The etching intensity plot of FIG. 4 starts with a minimal amount of intensity and then begins to ramp the intensity up at the Start ONO Step, which begins the first etch cycle of the cyclic etching process in box 241 of the method 200. The etching intensity continues to linearly increase to a configurable maximum intensity, that once reached will begin to ramp down. While the intensity linearly decreases, the etching of the ONO layers continues, which may cause over-etch on underlying layers beneath the ONO stack if an etch stop layer is not used. By using etch stop layers to etch various features of different etch rates simultaneously, over-etch damage to an underlayer may be minimized. As a result, the first etch time (t₁) may be adjusted to ensure slower etch rate features land on the topmost etch stop layer without over-etching an underlying layer or damaging circuitry beneath the layer stack of the layer stack substrate.

The first maximum of the etching intensity may be the ONO Step End Point, and the timeframe between the Start ONO Step and the Start ESL Step is the first etch time (t₁) of the first etch process in box 241 of the method 200. After reaching the ONO Step End Point, the etching intensity linearly decreases back down to the initial value, which ends the first selective etch step used to etch the ONO layers of the layer stack substrate. The cyclic etching process switches to the second etch step of the etch cycle in box 242 to etch the topmost etch stop layer of the layer stack at the point labeled Start ESL Step.

The first Start ESL Step corresponds to the second etch step of the etch cycle in box 242 of the method 200. The topmost ONO layers of the layer stack substrate has been etched such that the various features of different etch rates have all landed on the topmost etch stop layer with minimal over-etch of the topmost etch stop layer due to the selectivity of the first etch recipe. At the Start ESL Step, the etching intensity begins to linearly ramp up and start the etching of the various features through the topmost etch stop layer, which corresponds to starting the second selective etch step of the etch cycle in box 242 of the method 200. The etching intensity linearly increases to the same maximum level to the point labeled ESL Step End Point.

The cyclic etching process then begins to ramp the etching intensity linearly down from the configurable maximum, and again over-etch may occur on the topmost layer of the ONO layer stack beneath the topmost etch stop layer. As a result of the selective etch process, over-etch may be minimized on the underlying ONO layer. Consequently, the second selective etch step negligibly effects the underlying ONO uppermost layer and may be used to ensure the completion of smaller etch rate features land atop the uppermost layer of the ONO layer stack. The etching intensity linearly decreases to the initial level again, which may be the end of the second selective etch step, and completes an entire etch cycle of the cyclic etch process in boxes 241-242 of the method 200. The second etch time (t₂) corresponds to the timeframe between the Start ESL Step and the next Start ONO Step. In other words, the second etch time (t₂) is the timeframe of the second selective etch step of the cyclic etch process in box 242 of the method 200. And similar to the first etch time (t₁), the second etch time (t₂) may also be adjusted to ensure the slower etch rate features land on the topmost layer of the ONO layer stack with minimal over-etch.

In various embodiments, the first etch time (t₁) and the second etch time (t₂) may be different amounts of time. In other embodiments, the first etch time (t₁) and the second etch time (t₂) may be the same amount of time. And in further embodiments, the first etch time (t₁) and the second etch time (t₂) may change as a function of the depth of the features being etched. And in even further embodiments, only one of either the first etch time (t₁) or the second etch time (t₂) may vary as the cyclic etching process continues.

At this point, the cyclic etching process switches to the first selective etch step, which begins a new etch cycle at the point labeled Start ONO Step. A single layer stack has now been etched with minimal over-etch to the underlying layers of the layer stack substrate. This point may be illustrated by the semiconductor device 300 in FIG. 3L where only one of the layer stacks 310 have been etched through. At this point, the new etch cycle proceeds through similar steps as described above. The cyclic etching process continues to linearly increase and linearly decrease the etching intensity based on which selective etch step may be currently etching until the total number of etch stop layers according to the process recipe have been etched through.

The method 200 of FIG. 2 describes a fabrication method in an embodiment with etch stop layers deposited with equal numbers of first and second layers between the multiple etch stop layers. Other embodiment methods without evenly spaced etch stop layers or with varying thicknesses of the etch stop layers may also be used, such as the embodiments illustrated in FIGS. 5A-5C.

FIGS. 5A-5C illustrate semiconductor devices fabricated using different embodiment methods to deposit multiple etch stop layers. FIG. 5A illustrates a semiconductor device 500a fabricated using an embodiment method with evenly spaced etch stop layers of the same thickness. FIG. 5B illustrates a semiconductor device 500b fabricated using an embodiment method with evenly spaced etch stop layers of varying thicknesses. And FIG. 5C illustrates a semiconductor device 500c fabricated using an embodiment method with unevenly spaced etch stop layers of the same thickness.

The semiconductor device 500a illustrated in FIG. 5A comprises an underlayer 503 disposed above a wafer 501 to form a substrate 502. The semiconductor device 500a further comprises a first etch stop layer 504a of thickness h₁, a second etch stop layer 504b of thickness h₂, and a third etch stop layer 504c of thickness h₃. Further, the semiconductor device 500a comprises alternating layers of a first layer 506 and a second layer 508 disposed over the etch stop layers 504a-c.

The semiconductor device 500a further comprises a first layer stack 520a, a second layer stack 520b, and a third layer stack 520c, and each of the layer stacks 520a-c comprises alternating first layers 506 and second layers 508. The first layer stack 520a is of a thickness d₁, the second layer stack 520b is of a thickness d₂, and the third layer stack 520c is of a thickness d₃. The first layer stack 520a is disposed between the first etch stop layer 504a and the second etch stop layer 504b. The second layer stack 520b is disposed between the second etch stop layer 504b and the third etch stop layer 504c. And the third layer stack 520c is disposed over the third etch stop layer 504c.

The embodiment fabrication method used to fabricate the semiconductor device 500a used the same thickness for each of the etch stop layers 504a-c, such that h₁ is equal to h₂, and h₂ is equal to h₃, or h₁=h₂=h₃. The embodiment fabrication method used for the semiconductor device 500a deposited the same number of first layers 506 and second layers 508 when forming the layer stacks 520a-c, such that d₁ is equal to d₂, and d₂ is equal to d₃, or d₁=d₂=d₃. For example, the method 200 of FIG. 2 may be used to fabricate the semiconductor device 500a of FIG. 5A without modifying the method 200.

The semiconductor device 500b illustrated in FIG. 5B comprises the same elements as the semiconductor device 500a and all of the elements may be of the same materials described in the detailed description of FIGS. 3A-30. As opposed to the semiconductor device 500a, the semiconductor device 500b comprises a first etch stop layer 510a of thickness h₁, a second etch stop layer 510b of thickness h₂, and a third etch stop layer 510c of thickness h₃. Further, the semiconductor device 500b comprises alternating layers of the first layer 506 and the second layer 508 disposed over the etch stop layers 510a-c. The semiconductor device 500b further comprises a first layer stack 522a, a second layer stack 522b, and a third layer stack 522c. The first layer stack 522a is of a thickness d₁, the second layer stack 522b is of a thickness d₂, and the third layer stack 522c is of a thickness d₃.

The difference between semiconductor device 500b and semiconductor device 500a is the thicknesses of the etch stop layers 510a-c of semiconductor device 500b may vary in thickness. Specifically, as illustrated in FIG. 5B, the etch stop layers 510a-c deposited towards the exposed surface further away from the substrate 502 may be thinner than those deposited deep within the stack. Similar to the semiconductor device 500a, the layer stacks 522a-c of the semiconductor device 500b may comprise the same number of first layers 506 and second layers 508, such that d₁ is equal to d₂, and d₂ is equal to d₃, or d₁=d₂=d₃.

The semiconductor device 500c illustrated in FIG. 5C also comprises the same elements as the semiconductor device 500a and all of the elements may be of the same materials described in the detailed description of FIGS. 3A-30. The semiconductor device 500c comprises a first etch stop layer 512a of thickness h₁, a second etch stop layer 512b of thickness h₂, and a third etch stop layer 512c of thickness h₃. The semiconductor device 500c further comprises a first layer stack 524a, a second layer stack 524b, and a third layer stack 524c. The first layer stack 524a is of a thickness d₁, the second layer stack 524b is of a thickness d₂, and the third layer stack 524c is of a thickness d₃.

The difference between semiconductor device 500c and semiconductor device 500a is the number of first layers 506 and second layers 508 of each of the layer stacks 524a-c changes, such that d₁ is less than d₂, and d₂ is less than d₃, or d₁<d₂<d₃. Similar to the semiconductor device 500a, the etch stop layers 512a-c of the semiconductor device 500c are deposited with the same thicknesses, such that h₁ is equal to h₂, and h₂ is equal to h₃, or h₁=h₂=h₃.

Though the semiconductor devices 500a-c of FIGS. 5A-5C are illustrated with three etch stop layers, other embodiments may use more, such as embodiments with the number of etch stop layers being between about 2 to about 50 etch stop layers. In various embodiments, the number of etch stop layers may be a ratio with the number of layer pairs, such as 1 etch stop layer for every 50 layer pairs, or 1:50 etch stop layers to layer pairs. Other embodiments may use combinations of the different etch stop layer embodiments illustrated in FIGS. 5A-5C, such as using etch stop layers of varying thickness deposited with different amounts of first and second layers between.

A similar cyclic etch process to the cyclic etch process described for the method 200 in FIG. 2 and represented by the plot of etching intensity as a function of time of FIG. 4 may be used to etch the semiconductor devices 500a-c with some modifications. For example, to etch the semiconductor device 500b, the cyclic etching process may increase the second etch time t₂ as the cyclic etch process commences in order to effectively punch through the etch stop layers 510a-c because of their increasing thicknesses.

FIG. 6 illustrates a plasma etching tool 600 that may implement the cyclic etching process of the fabrication method of this disclosure in accordance with various embodiments. For example, the plasma etching tool 600 may implement the cyclic etching process illustrated in the flowchart in box 240 of FIG. 2. In various embodiments, the plasma etching tool 600 may be configured to selectively etch the layer stack using a first etch step to simultaneously etch different features through the alternating first and second layers and a second etch step to selectively etch and punch through the etch stop layers.

The first selective etch step comprises using a first gas chemistry that, when ignited into a plasma and used to etch the layer stack, effectively etches the materials of the first and second layers with minimal damage to the etch stop layer once the etch stop layer is exposed. The second selective etch step comprises using a second gas chemistry that, when ignited into a plasma and used to etch the layer stack, effectively etches the material of the etch stop layer with minimal damage to the first or second layers once the etch stop layer is etched through. The plasma etching tool 600 may be configured to selectively etch the layer stack by switching between the first gas chemistry and the second gas chemistry.

In an embodiment where the first layer of the layer stack is silicon nitride, the second layer of the layer stack is silicon oxide, and the etch stop layer is TiO₂, the first gas chemistry used may be one that selectively etches silicon nitride and silicon oxide without etching the etch stop layer. For example, gases such as C₄F₆, C₄F₈, C₃F₈, CH₃F, CH₂F₂, or CHF₃ are mixed with Ar, Kr, O₂, or N₂ to ensure a high anisotropy and a high selectivity over TiO₂ (as well as silicon, which may be the material of the substrate). In one or more embodiments, silicon nitride and silicon oxide layers may be etched using CH₃F/O₂. In other embodiments, silicon nitride and silicon oxide layers may be etched using one or all of CH₃F, CH₂F₂, and CHF₃ combined with O₂. Other gases such as Ar, Kr, N₂, and etcetera may be used. In various embodiments, any plasma capable of etching silicon nitride and silicon oxide selective to TiO₂ may be used.

In a similar embodiment, the second gas chemistry used may be one that selectively etches TiO₂. For example, a chlorine (Cl₂) gas may be used to selectively etch TiO₂.

The plasma etching tool 600 comprises a plasma processing chamber 650 configured to sustain plasma directly above a substrate 602 loaded onto a substrate holder 610. A process gas, such as the first gas chemistry or the second gas chemistry mentioned above, may be introduced to the plasma processing chamber 650 through a gas inlet 622 and may be pumped out of the plasma processing chamber 650 through a gas outlet 624. The gas inlet 622 and the gas outlet 624 may comprise a set of multiple gas inlets and gas outlets, respectively. The gas flow rates, the gas chemistry used, and the chamber pressure may be controlled by an inlet gas flow control system 620 coupled to the gas inlet 622. The inlet gas flow control system 620 may also implement the cyclic etching process of this disclosure. The outflow gas composition may be monitored using an outlet gas flow control system 626 coupled to the gas outlet 624. In an embodiment, the outflow gas composition results determined by the outlet gas flow control system 626 may be used as a dynamic trigger for switching between the selective etch steps of the etch cycle, such as the etch cycle illustrated in the plot of FIG. 4. In another embodiment, the plasma etching tool 600 may switch between the selective etch steps according to the etch times included in the feature recipe. The inlet gas flow control system 620 and the outlet gas flow control system 624 may comprise various components such as high-pressure gas canisters, valves (e.g., throttle valves), pressure sensors, gas flow sensors, gas analyzers, vacuum pumps, pipes, and electronically programmable controllers.

The plasma etching tool 600 may further comprise an RF bias power source 660 and an RF source power source 630. The RF bias power source 660 and the RF source power source 630 may be coupled to respective electrodes of the plasma etching tool 600. The substrate holder 610 may also be the electrode coupled to the RF bias power source 660. The RF source power source 630 is illustrated coupled to a helical electrode 632 coiled around a dielectric sidewall 616. In FIG. 6, the gas inlet 622 may be an opening in a top plate 612 and the gas outlet 624 may be an opening in a bottom plate 614. The top plate 612 and bottom plate 614 may be conductive and electrically connected to the system ground (a reference potential).

The plasma etching tool 600 illustrated in FIG. 6 is for example only. In various alternative embodiments, the plasma etching tool 600 may be configured with different couplings of the RF source power source 630 and the RF bias power source 660. In other embodiments, gas inlets and outlets may be coupled to sidewalls of the plasma processing chamber 650. In other embodiments, the outflow gas flow control system 626 does not actively monitor the gas composition of the gas flowing out of the plasma processing chamber 650 through the gas outlet 624. As a result, the plasma etching tool 600 instead may implement the cyclic etching process with a static etch cycle (like illustrated in the plot of FIG. 4). In another embodiment, the plasma etching tool 600 may be capable of depositing the various first and second layers of the layer stack, and depositing and patterning a hard mask layer over the layer stack substrate, as well as etch the features of the feature recipe using the cyclic etching process of this disclosure.

Example embodiments of the invention are described below. Other embodiments can also be understood from the entirety of the specification as well as the claims filed herein.

Example 1. A method of forming a device includes receiving, in a processing chamber, a substrate having a layer stack comprising an etch stop layer, a stack of alternating oxide and nitride layers, and a patterned hard mask layer, the patterned hard mask layer comprising a pattern for forming a first features and a second features in the layer stack, the first features having a different geometric characteristic than the second features. And the method further includes performing, in the processing chamber, a cyclic etch process to expose an underlayer, each cycle of the cyclic etch process including a first etch step to etch through the alternating oxide and nitride layers, and a second etch step to etch through the etch stop layer.

Example 2. The method of example 1, where the first etch step uses a fluorocarbon gas mixture comprising C₄F₆, C₄F₈, C₃F₈, CH₃F, CH₂F₂, or CHF₃, mixed with Ar, Kr, O₂, or N₂.

Example 3. The method of one of examples 1 or 2, where the etch stop layer comprises TiO₂ and the second etch step uses a second gas comprising Cl₂ to etch through the etch stop layer.

Example 4. The method of one of examples 1 to 3, further includes selectively etching the nitride layers and the etch stop layer to form a support structure for the oxide layers and a plurality of gaps separating the oxide layers.

Example 5. The method of one of examples 1 to 4, further includes masking the second features and filling the plurality of gaps with a conductive material through the first features, where the conductive material forms a plurality of gates for a 3D NAND device.

Example 6. The method of one of examples 1 to 5, further includes masking the first features and filling the second features with a conductive material, where the conductive material forms a plurality of channels for a 3D NAND device.

Example 7. The method of one of examples 1 to 6, further includes filling the first features with a conductive metal to form a plurality of contact vias. The method further includes forming a 3D NAND device, an active region of the 3D NAND device being coupled using the plurality of contact vias.

Example 8. The method of one of examples 1 to 7, where the etch stop layer includes TiO₂, the oxide layer includes a silicon oxide layer, and the nitride layer includes a silicon nitride layer.

Example 9. The method of one of examples 1 to 8, where the first features are contact features, and the second features are slits.

Example 10. A method of forming a device includes receiving, in a processing chamber, a substrate having a layer stack and a patterned hard mask layer, the patterned hard mask layer comprising a pattern for forming a first features and a second features in the layer stack, the layer stack comprising alternating layers of a first pair and a second pair, the first pair comprising an etch stop layer and a first layer, and the second pair comprising a second layer and a third layer made of a same material as the first layer. And the method further includes performing, in the processing chamber, a cyclic etch process, each cycle of the cyclic etch process including using the patterned hard mask layer as an etch mask, performing a first etch process to expose the etch stop layer of the first pair, the first etch process selectively etching the first layer, the second layer, and the third layer to form a portion of the first features and a portion of the second features, the first features being etched at a different etch rate than the second features. The cyclic etch process further includes performing a second etch process to etch through the etch stop layer of the first pair of the layer stack, the second etch process selectively etching the etch stop layer. And where the cyclic etch process is performed until an underlayer below the layer stack is exposed.

Example 11. The method of example 10, further includes, after performing the cyclic etch process, etching the etch stop layer of the first pair and the second layer of the second pair, and forming a functional semiconductor device including the etch stop layer.

Example 12. The method of one of examples 10 or 11, further includes filling the first features with a conductive metal to form a plurality of contact vias, and forming a 3D NAND device, an active region of the 3D NAND device being coupled using the plurality of contact vias.

Example 13. The method of one of examples 10 to 12, where the etch stop layer includes TiO₂, the first layer includes a silicon oxide layer, the second layer includes a silicon nitride layer, the third layer includes a silicon oxide layer, the first features include contact features, and the second features include slits.

Example 14. The method of one of examples 10 to 13, where the layer stack includes 2ⁿ first pairs with 2ⁿ−1 second pairs disposed between each first pair such that there are 2²ⁿ layer pairs and 2²ⁿ⁺1 layers, where n is a natural number greater than 3.

Example 15. The method of one of examples 10 to 14, where the etch stop layers within the layer stack are all of the same thickness.

Example 16. The method of one of examples 10 to 15, where a thickness of the etch stop layers decreases in a direction from the underlayer proximate a bottom of the layer stack to a top of the layer stack.

Example 17. The method of one of examples 10 to 16, where a total number of second pairs between each first pair of the layer stack decreases in a direction from a top of the layer stack to the underlayer proximate to a bottom of the layer stack.

Example 18. A method of forming a 3D NAND device includes receiving, in a processing chamber, a substrate comprising an underlayer, a first layer pair of an etch stop layer and a silicon oxide layer, and a plurality of second layer pairs, each second layer pair of the plurality of second layer pairs comprising a silicon nitride layer and a silicon oxide layer, the first layer pair and the plurality of second layer pairs being stacked to form a layer stack. The method further includes determining a total number of first layer pairs in the layer stack, where the total number of first layer pairs is at least 4. The method further includes determining a number of etch cycles for a cyclic etching process based on the total number of first layer pairs. The method further includes etching, in the processing chamber, a plurality of gate patterns and channel holes through the layer stack using the cyclic etching process, the cyclic etching process being repeated for the number of etch cycles, each cycle of the cyclic etch process including a first etching process to selectively etch the silicon oxide layers and the silicon nitride layers and a second etching process to selectively etch the etch stop layers. And the method further includes performing, in the processing chamber, a pull process to etch the silicon nitride layers and the etch stop layers of the layer stack.

Example 19. The method of example 18, further includes filling the plurality of gate patterns with a gate stack material and the channel holes with a channel material.

Example 20. The method of one of example 18 or 19, where the layer stack is formed by stacking one first layer pair and then stacking the plurality of second layer pairs on the first layer pair, and then repeating until the layer stack is formed.

Example 21. A method of forming a device includes performing a first cyclic process to deposit a first layer pair including an etch stop layer and an oxide layer, the oxide layer disposed over the etch stop layer. The method further includes performing a second cyclic process to deposit a plurality of second layer pairs over the first layer pair, each second layer pair includes a nitride layer and an oxide layer disposed over the nitride layer, the second cyclic process including 2n cycles to form 2n second layer pairs, where n is an integer of at least 8. After depositing the plurality of second layer pairs, the method further includes repeating the first cyclic process and the second cyclic process to form m layer stacks, each layer stack including one first layer pair and the plurality of second layer pairs, where m is an integer of at least 4. The method further includes forming a patterned hard mask layer over the m layer stacks, where the patterned hard mask layer includes a pattern for forming first features and second features. And the method further includes using the patterned hard mask layer as an etch mask, performing a third cyclic process to etch the m layer stacks and expose an underlayer below the layer stack, each cycle of the third cyclic process including a first etch step to selectively etch the nitride layers and the oxide layers and a second etch step to selectively etch the etch stop layer, a total number of cycles in the third cyclic process being m, and where the third cyclic process forms the first features and the second features, the first features having a different geometric characteristic than the second features.

Example 22. The method of example 21, further includes etching the etch stop layers and the nitride layers, and forming a functional semiconductor device including the etch stop layers.

Example 23. The method of one of examples 21 or 22, further includes filling the first features with a conductive metal to form a plurality of contact vias. And the method further includes forming a 3D NAND device, an active region of the 3D NAND device being coupled using the plurality of contact vias.

Example 24. The method of one of examples 21 to 23, where etching the etch stop layers and the nitride layers includes performing a pull process, the pull process being an isotropic etch process that selectively etches the etch stop layers and the nitride layers.

Example 25. The method of one of examples 21 to 24, where the first features are contact features and the second features are slits.

Example 26. The method of one of examples 21 to 25, where the conductive metal is tungsten.

Example 27. The method of one of examples 21 to 26, where the etch stop layer is TiO₂.

Example 28. The method of one of examples 21 to 27, further includes etching the etch stop layers and the oxide layers. And the method further includes forming a functional semiconductor device including the etch stop layers.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a device, the method comprising:
receiving, in a processing chamber, a substrate having a layer stack comprising an etch stop layer, a stack of alternating oxide and nitride layers, and a patterned hard mask layer, the patterned hard mask layer comprising a pattern for forming a first features and a second features in the layer stack, the first features having a different geometric characteristic than the second features; and
performing, in the processing chamber, a cyclic etch process to expose an underlayer, each cycle of the cyclic etch process comprising
a first etch step to etch through the alternating oxide and nitride layers, and
a second etch step to etch through the etch stop layer.

2. The method of claim 1, wherein the first etch step uses a fluorocarbon gas mixture comprising C₄F₆, C₄F₈, C₃F₈, CH₃F, CH₂F₂, or CHF₃, mixed with Ar, Kr, O₂, or N₂.

3. The method of claim 2, wherein the etch stop layer comprises TiO₂ and the second etch step uses a second gas comprising Cl₂ to etch through the etch stop layer.

4. The method of claim 1, further comprising:
selectively etching the nitride layers and the etch stop layer to form a support structure for the oxide layers and a plurality of gaps separating the oxide layers.

5. The method of claim 4, further comprising:
masking the second features and filling the plurality of gaps with a conductive material through the first features, wherein the conductive material forms a plurality of gates for a 3D NAND device.

6. The method of claim 4, further comprising:
masking the first features and filling the second features with a conductive material, wherein the conductive material forms a plurality of channels for a 3D NAND device.

7. The method of claim 1, further comprising:
filling the first features with a conductive metal to form a plurality of contact vias; and
forming a 3D NAND device, an active region of the 3D NAND device being coupled using the plurality of contact vias.

8. The method of claim 1, wherein the etch stop layer comprises TiO₂, the oxide layer comprises a silicon oxide layer, and the nitride layer comprises a silicon nitride layer.

9. The method of claim 1, wherein the first features are contact features, and the second features are slits.

10. A method of forming a device, the method comprising:
receiving, in a processing chamber, a substrate having a layer stack and a patterned hard mask layer, the patterned hard mask layer comprising a pattern for forming a first features and a second features in the layer stack, the layer stack comprising alternating layers of a first pair and a second pair, the first pair comprising an etch stop layer and a first layer, and the second pair comprising a second layer and a third layer made of a same material as the first layer; and
performing, in the processing chamber, a cyclic etch process, each cycle of the cyclic etch process comprising
using the patterned hard mask layer as an etch mask, performing a first etch process to expose the etch stop layer of the first pair, the first etch process selectively etching the first layer, the second layer, and the third layer to form a portion of the first features and a portion of the second features, the first features being etched at a different etch rate than the second features,
performing a second etch process to etch through the etch stop layer of the first pair of the layer stack, the second etch process selectively etching the etch stop layer, and
wherein the cyclic etch process is performed until an underlayer below the layer stack is exposed.

11. The method of claim 10, further comprising:
after performing the cyclic etch process, etching the etch stop layer of the first pair and the second layer of the second pair, and forming a functional semiconductor device comprising the etch stop layer.

12. The method of claim 11, further comprising:
filling the first features with a conductive metal to form a plurality of contact vias, wherein the conductive metal comprises tungsten; and
forming a 3D NAND device, an active region of the 3D NAND device being coupled using the plurality of contact vias.

13. The method of claim 10, wherein the etch stop layer comprises TiO₂, the first layer comprises a silicon oxide layer, the second layer comprises a silicon nitride layer, the third layer comprises a silicon oxide layer, the first features comprise contact features, and the second features comprise slits.

14. The method of claim 10, wherein the layer stack comprises 2ⁿ first pairs with 2ⁿ−1 second pairs disposed between each first pair such that there are 2²ⁿ layer pairs and 2²ⁿ⁺1 layers, where n is a natural number greater than 3.

15. The method of claim 10, wherein the etch stop layers within the layer stack are all of the same thickness.

16. The method of claim 10, wherein a thickness of the etch stop layers decreases in a direction from the underlayer proximate a bottom of the layer stack to a top of the layer stack.

17. The method of claim 10, wherein a total number of second pairs between each first pair of the layer stack decreases in a direction from a top of the layer stack to the underlayer proximate to a bottom of the layer stack.

18. A method of forming a 3D NAND device, the method comprising:
receiving, in a processing chamber, a substrate comprising an underlayer, a first layer pair of an etch stop layer and a silicon oxide layer, and a plurality of second layer pairs, each second layer pair of the plurality of second layer pairs comprising a silicon nitride layer and a silicon oxide layer, the first layer pair and the plurality of second layer pairs being stacked to form a layer stack;
determining a total number of first layer pairs in the layer stack, wherein the total number of first layer pairs is at least 4;
determining a number of etch cycles for a cyclic etching process based on the total number of first layer pairs;
etching, in the processing chamber, a plurality of gate patterns and channel holes through the layer stack using the cyclic etching process, the cyclic etching process being repeated for the number of etch cycles, each cycle of the cyclic etch process comprising a first etching process to selectively etch the silicon oxide layers and the silicon nitride layers and a second etching process to selectively etch the etch stop layers; and
performing, in the processing chamber, a pull process to etch the silicon nitride layers and the etch stop layers of the layer stack.

19. The method of claim 18, further comprising:
filling the plurality of gate patterns with a gate stack material and the channel holes with a channel material.

20. The method of claim 18, wherein the layer stack is formed by stacking one first layer pair and then stacking the plurality of second layer pairs on the first layer pair, and then repeating until the layer stack is formed.
